(19) United States
(12) Patent Application Publication
(10) Pub. No.: US 2013/0286296 A1
(43) Pub. Date: Oct. 31, 2013

(54) TELEVISION RECEIVER AND ELECTRONIC DEVICE

(71) Applicant: KABUSHIKI KAISHA TOSHIBA, Tokyo (JP)

(72) Inventors: Tomoko KITAMURA, Tokyo (JP); Tetsuhiko FUKAZAWA, Tokyo (JP)

(73) Assignee: Kabushiki Kaisha Toshiba, Tokyo (JP)

(21) Appl. No.: 13/725,584

(22) Filed: Dec. 21, 2012

(30) Foreign Application Priority Data
Apr. 25, 2012 (JP) 2012-100373

(51) Int. Cl. H04N 5/64; H05K 5/02

(52) U.S. Cl. CPC H04N 5/64; H05K 5/0247
USPC 348/836; 361/679.01

(57) ABSTRACT

According to one embodiment, A television receiver includes: a display device comprising a screen; a first housing configured to house at least a part of the display device in a state exposing the screen, the first housing comprising an accommodating part and a first connector facing the accommodating part; a second housing configured to be detachably accommodated in the accommodating part, the second housing comprising a second connector configured to be electrically connected to the first connector; a cover configured to cover the accommodating part and to be removably placed on the first housing; and a first buffer between the second housing and the cover, the first buffer being configured to extend in a longitudinal direction of the accommodating part.

### CROSS-REFERENCE TO RELATED APPLICATIONS

This application is based upon and claims the benefit of priority from Japanese Patent Application No. 2012-100373, filed Apr. 25, 2012, the entire contents of which are incorporated herein by reference.

### FIELD

Embodiments described herein relate generally to a television receiver and an electronic device.

### BACKGROUND

Conventionally known is an electronic device that comprises a housing provided with an accommodating part for accommodating a module, and in which a connector on the housing is electrically connected to a connector on the module.

In this type of electronic device, it has been desired to reduce an impact of an external force applied to the module, as an example.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view illustrating an example of a television receiver according to a first embodiment;

FIG. 2 is an exemplary side view illustrating an example of the television receiver in the first embodiment;

FIG. 3 is an exemplary perspective view illustrating a module and a holder accommodated in the television receiver in the first embodiment;

FIG. 4 is an exemplary perspective view of the example of the module and the holder illustrated in FIG. 3, viewed from another angle;

FIG. 5 is an exemplary perspective view illustrating the module housed in the television receiver in the first embodiment;

FIG. 6 is an exemplary exploded perspective view illustrating the example of the module housed in the television receiver in the first embodiment;

FIG. 7 is an exemplary perspective view illustrating the holder of the module housed in the television receiver in the first embodiment;

FIG. 8 is an exemplary plan view (rear view) illustrating an example of an accommodating part provided in the television receiver in the first embodiment;

FIG. 9 is an exemplary plan view (rear view) illustrating an example of the module housed in the accommodating part illustrated in FIG. 8, without connectors being electrically connected;

FIG. 10 is an exemplary plan view (rear view) illustrating an example of the module housed in the accommodating part illustrated in FIG. 8, with the connectors being electrically connected;

FIG. 11 is an exemplary plan view (rear view) illustrating an example of the accommodating part in which the module illustrated in FIG. 10 is accommodated, and that is covered by a cover;

FIG. 12 is an exemplary cross-sectional view, in a plan view (rear view), illustrating an example of the connector provided to a housing and the connector provided to the module before being electrically connected to each other in the television receiver in the first embodiment;

FIG. 13 is an exemplary cross-sectional view, in a plan view (rear view), illustrating an example of the connectors illustrated in FIG. 12 being electrically connected;

FIG. 14 is an exemplary schematic illustrating an example of the module at a first position at a cross section equivalent to the cross section across XV-XV in FIG. 13;

FIG. 15 is an exemplary cross-sectional view across XV-XV in FIG. 13;

FIG. 16 is an exemplary perspective view of the cover illustrated in FIG. 11;

FIG. 17 is an exemplary schematic illustrating a cross section across XVII-XVII in FIG. 11;

FIG. 18 is an exemplary schematic illustrating a cross section across XVIII-XVIII in FIG. 11;

FIG. 19 is an exemplary perspective view illustrating an electronic device in a second embodiment;

FIG. 20 is an exemplary plan view (bottom view, rear view) illustrating an example of a first housing of the electronic device in the second embodiment;

FIG. 21 is an exemplary plan view (bottom view, rear view) illustrating an example of an accommodating part provided to the first housing of the electronic device in the second embodiment;

FIG. 22 is an exemplary schematic illustrating a cross section across XXII-XXII in FIG. 20; and

FIG. 23 is an exemplary schematic illustrating a cross section across XXIII-XXIII in FIG. 20.

### DETAILED DESCRIPTION

In general, according to one embodiment, A television receiver comprises: a display device comprising a screen; a first housing configured to house at least a part of the display device in a state exposing the screen, the first housing comprising an accommodating part and a first connector facing the accommodating part; a second housing configured to be detachably accommodated in the accommodating part, the second housing comprising a second connector configured to be electrically connected to the first connector; a cover configured to cover the accommodating part and to be removably placed on the first housing; and a first buffer between the second housing and the cover, the first buffer being configured to extend in a longitudinal direction of the accommodating part.

In exemplary embodiments to be described below, some common elements are included. Therefore, in explanations below, the same reference numerals are assigned to the same elements, and redundant explanations of the same elements are partially omitted. Parts included in one of the embodiments may be replaced with corresponding parts included in the other embodiments. Unless otherwise specified, a part included in one of the embodiments has the same structure and placed at the same position as that in the other embodiments. In each of the drawings, directions (an X direction, a Y direction, and a Z direction) are illustrated for convenience. The X direction corresponds to the longitudinal direction of a wall 3a of a housing 3A or a first housing 3B in a front view (hereinafter, referred to, seen in a plan view, in the embodiments). The Y direction corresponds to the short side direction of the wall 3a of the housing 3A or the first housing 3B in the front view (plan view). The Z direction corresponds to the thickness direction of the housing 3A or the first housing 3B. The X direction, the Y direction, and the Z direction perpendicularly cross each other.

In the embodiments to be described below, explained as an example is an electronic device configured as a television receiver or a personal computer; however, the electronic device according to the embodiments is not limited thereto. For example, the electronic device according to the embodiment may be various electronic devices, such as a smartphone, a smart book, a cellular phone, a personal digital assistant (PDA), a video display device, a video phone, a video display device, and information storage device, comprising an accommodating part where a module is accommodated.

### First Embodiment

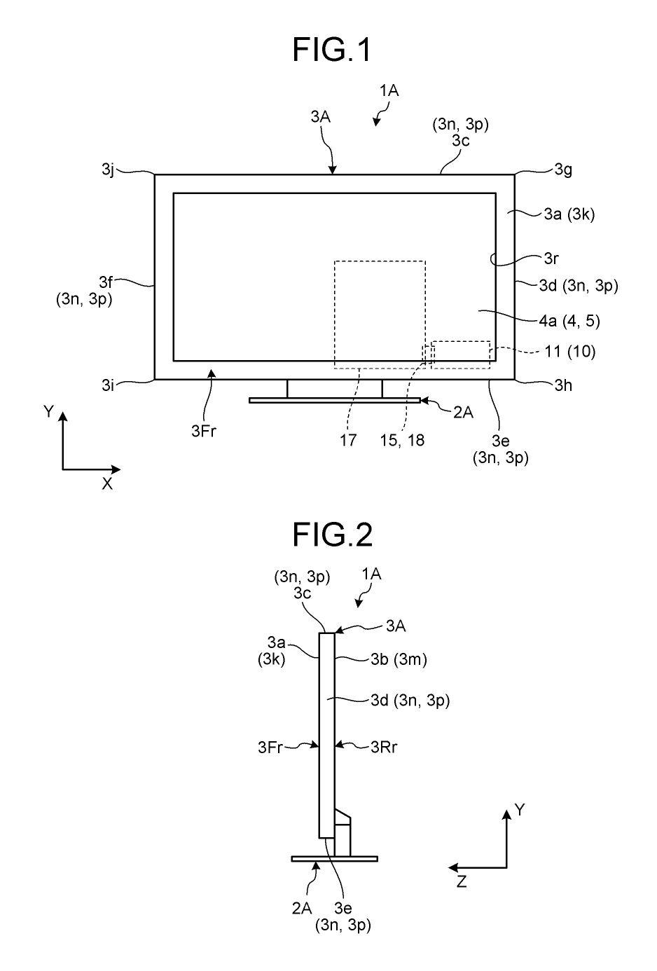

A television receiver 1A that is an example of an electronic device according to a first embodiment comprises a support 2A (a supporting portion, a station, a stand) and the housing 3A (a first housing), as illustrated in FIGS. 1 and 2. Specifically, the support 2A is placed on a setting area such as a desk, a shelf, and a table (setting surface not illustrated), and supports the housing 3A at an upright orientation. The support 2A may support the housing 3A fixedly, or may support the housing 3A movably (rotatably, slidably). The support 2A may be movable (rotatable) with respect to the housing 3A by being tilted, swiveled, or pivoted, for example.

In the first embodiment, as maybe understood from FIG. 1, the housing 3A has an external appearance of a rectangular shape (in the first embodiment, an oblong shape, as an example) in the front view (and the rear view), as an example. The housing 3A also has a cuboid shape that is thin and flat in the front-back direction (the thickness direction of the housing 3A, the Z direction), as illustrated in FIG. 2. The housing 3A has a surface 3a (a frontal surface, a front surface, a surface portion) and a surface 3b (a back surface, a rear surface, a surface portion) located on the opposite side of the housing 3A. The surface 3a and the surface 3b are laid approximately in parallel (in the first embodiment, in parallel, as an example). The housing 3A also has four ends 3c to 3f (sides, edge portions) and four corners 3g to 3j (pointed portions, curved portions, ends) in the front view, as illustrated in FIG. 1. The ends 3c and 3e are examples of longer sides. The ends 3d and 3f are examples of shorter sides. The housing 3A functions as an accommodating part where components (not illustrated) are accommodated, as an example, and may also function as a support for supporting an object with some weight (e.g., a display device 4 or a component).

The housing 3A comprises a wall 3k (a part, a plate, a frame, a front wall, a frontal wall, a top wall) including the surface 3a, and a wall 3m (a part, a plate, a rear wall, a back wall, a bottom wall) including the surface 3b. The walls 3k and 3m both have a rectangular shape (in the first embodiment, an oblong shape, as an example). The wall 3k also has a frame-like shape, and the wall 3m has a plate-like shape. The housing 3A has four walls 3n (parts, plates, side walls, end walls, standing walls, stretched portions) each of which includes a surface 3p (a surface, a circumferential surface) stretching between the wall 3k and the wall 3m. A rectangular opening 3r is formed on the wall 3k.

The housing 3A is made from a combination of a plurality of parts (divided portions, members). The housing 3A comprises a first member 3Fr (a first part, a front side member, a cover, a bezel, a frame) including at least the wall 3k, and a second member 3Rr (a second part, a rear side member, a base, a bottom, a plate, a cover) at least including the wall 3m, as an example. In the first embodiment, the walls 3n are configured as a part of the second member 3Rr. The housing 3A may also comprise a third member (a third part, an intermediate member, an inner, a middle frame, a middle plate, not illustrated), in addition to the first member 3Fr and the second member 3Rr. Some part of the walls 3k, 3m, and 3n may be included as a part of the third member. The first member 3Fr, the second member 3Rr, the third member, and the like may be made of a metallic material or a synthetic resin material, for example.

In the first embodiment, as an example, the display device 4 (display unit, display, panel, display component) is housed in the housing 3A. Specifically, a screen 4a of the display device 4 located on the side of the surface 3a is exposed to the front side (outside) of the housing 3A through the opening 3r. A user can view the screen 4a from the front side through the opening 3r. The display device 4 has an external appearance of a rectangular shape (in the first embodiment, an oblong shape, as an example) in the front view. The display device 4 also has a cuboid shape that is thin and flat in the front-back direction. The display device 4 is a liquid crystal display (LCD), an organic electro-luminescent display (GELD), or a plasma display panel (PDP), for example.

In the first embodiment, as an example, a transparent, relatively thin, and rectangular input operation panel 5 (as an example, a touch panel, a touch sensor, an operation surface, an input operation module, an input receiving module) is placed on the front side (frontal side, the side of the wall 3k) of the display device 4. The input operation panel 5 covers the screen 4a. An operator (e.g., a user) can make inputs by making operations such as touching, pressing, rubbing the input operation panel 5, or moving a hand, a finger, or stylus near the input operation panel 5. Light output from the screen 4a of the display device 4 passes through the input operation panel 5 and travels to the front side (outside) of the housing 3A through the opening 3r on the wall 3k. The input operation panel 5 is an example of an input module. In the first embodiment, as an example, the display device 4 and the input operation panel 5 are fixed to (supported by) one of the first member 3Fr, the second member 3Rr, and the third member using fixtures (fixing parts, clamps; e.g., screws, clamps, or parts, not illustrated), an adhesive (e.g., an adhesive agent, or a double-sided adhesive tape, not illustrated), and the like.

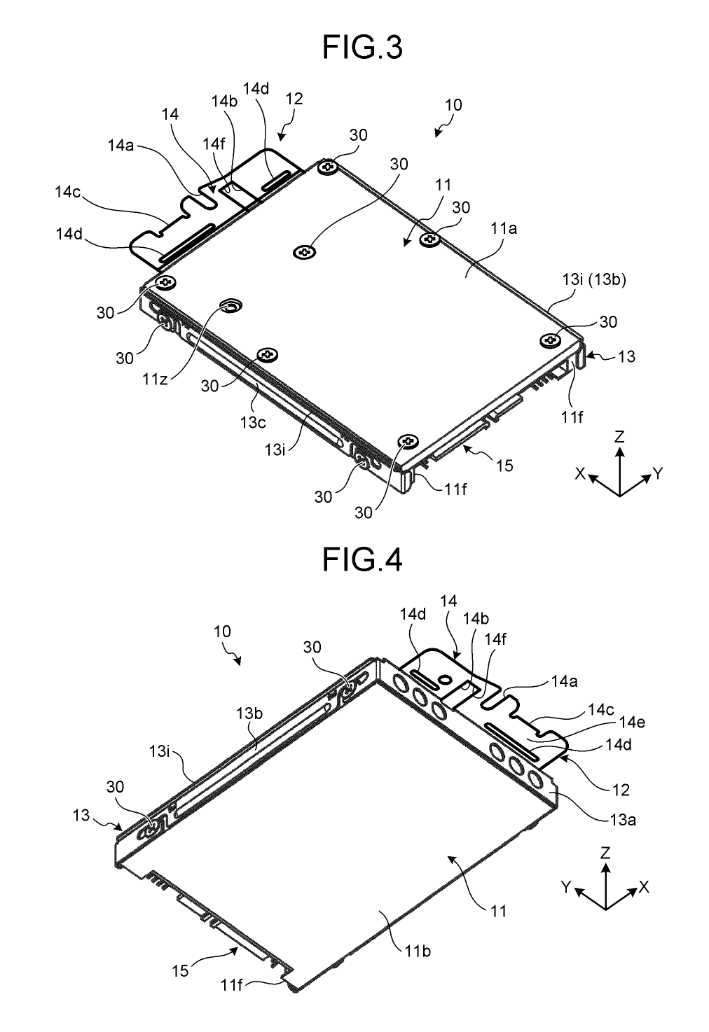

In the first embodiment, as an example, as illustrated in FIGS. 3 and 4, a sub-assembly 10 comprises a module 11 (an electric component, an electronic component, attachment parts, parts) and a holder 12 (a support, an attaching portion, an intermediating portion, an attachment, an adjuster, a supporting member, an attaching member, an auxiliary member, parts). The module 11 is a hard disk drive (HDD) in the first embodiment, as an example. The module 11 can be mounted onto the housing 3A in a removable manner. The module 11 may also be an optical disk drive (ODD) or a solid state drive (SSD), for example. The sub-assembly 10 is also an example of a module.

In the first embodiment, as an example, as illustrated in FIGS. 3 to 6, the module 11 is configured as a flat cuboid. The module 11 has an external appearance of a rectangular shape (in the first embodiment, an oblong shape, as an example) in a plan view, viewed from a direction of a first surface 11a or a second surface 11b located on the opposite side of the first surface 11a (viewed in the thickness direction, viewed in the Z direction).

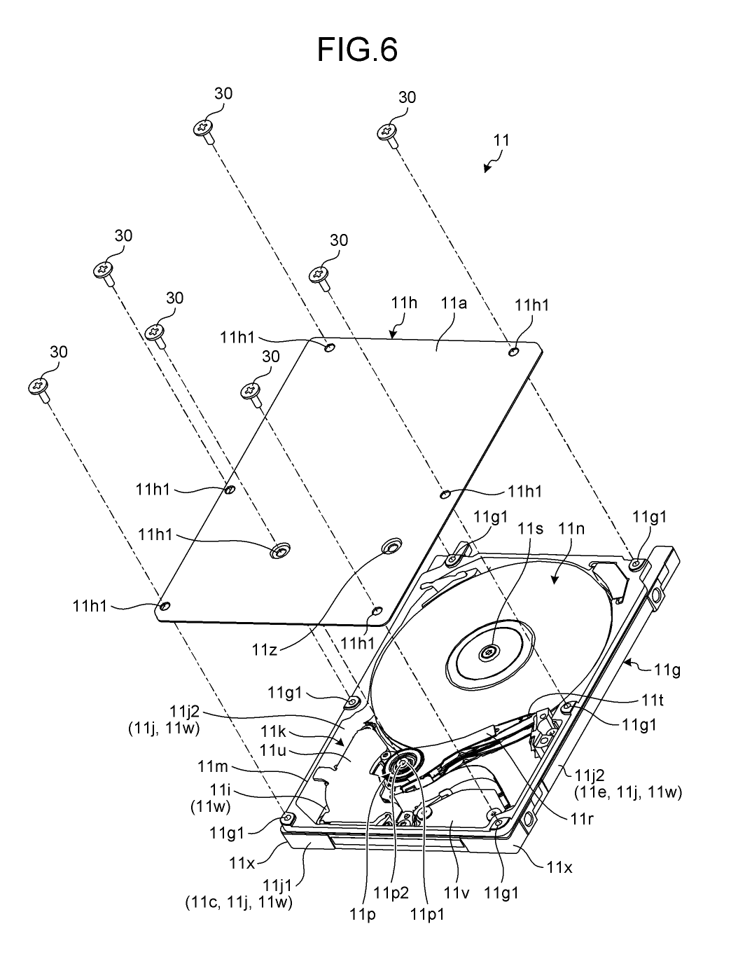

In the first embodiment, as an example, as illustrated in FIG. 6, the module 11 comprises a first member 11g (a case, an accommodating part, abase portion) and a second member 11h (a wall, a lid, a cover). The first member 11g and the second member 11h are examples of a housing 11w of the module 11 (a second housing). The housing 11w may be made of a metallic material or a synthetic resin material, for example. The housing 11w of the module 11 (second housing) may be made from two or more members.

The first member 11g has a rectangular shape (in the first embodiment, an oblong shape, as an example), and is configured as a case having a relatively thin cuboid shape that comprises a plate-like wall 11i (a bottom wall, a lower wall, a lateral wall) and a band-like and plate-like wall 11j (a side wall, a standing wall) surrounding the wall 11i and extending at an approximately constant height. In other words, the first member 11g comprises an accommodating part 11k surrounded by the walls 11i and 11j, and an opening 11m that opens the accommodating part 11k. The opening 11m is covered and closed by the second member 11h (a wall) having a rectangular (in the first embodiment, an oblong shape, as an example), plate-like shape. The first member 11g comprises a plurality of coupling portions 11g1 (in the first embodiment, female screw holes, as an example). The second member 11h comprises coupling portions 11h1 arranged at positions corresponding to the positions of the coupling portions 11g1. Couplers 30 (in the first embodiment, screws, as an example) passed through the respective coupling portions 11h1 are coupled to the respective coupling portions 11h1, and, in this manner, the first member 11g and the second member 11h are coupled to each other. The first member and the second member may have a different shape.

A disk 11n, a shaft 11p, an arm 11r, an actuator 11u, a controlling circuit 11v, and the like being parts are housed in the first member 11g. The disk 11n is a magnetic disk, and is supported by a shaft 11s located at the center (in the middle) of the disk 11n, in a manner rotatable about the shaft 11s. A plurality of disks 11n may be stacked in the module 11. The arm 11r is rotatably (swingably) supported by the shaft 11p that is placed at a position offset from the disk 11n. A head 11t is provided at the tip of the arm 11r, in a manner facing the disk 11n. The head 11t magnetically reads or writes data from or to the disk 11n. In a configuration where a plurality of the disks 11n are provided to the module 11, the arm 11r and the head 11t are provided correspondingly to each of the disks 11n.

The shaft 11p extends between the wall 11i of the first member 11g and the second member 11h, and ends of the shaft 11p are respectively supported by the wall 11i and the second member 11h. A coupling portion 11p2 (in the first embodiment, a female screw hole, as an example) is provided on an end 11p1 of the shaft 11p, being the end located on the side of the second member 11h. The coupling portion 11h1 (in the first embodiment, an opening, as an example) is provided to the second member 11h, at a position corresponding to the position of the coupling portion 11p2. A coupler 30 (in the first embodiment, a screw, as an example) passed through the coupling portion 11h1 is coupled to the coupling portion 11p2. In this manner, the shaft 11p and the second member 11h are coupled to each other.

In the first embodiment, as illustrated in FIGS. 3, 5, and 6, a ventilation hole 11z (opening; in the first embodiment, a penetrating hole, as an example) is provided to the second member 11h (wall portion, first surface 11a), as an example. In the first embodiment, the ventilation hole 11z is provided at a position not overlapping with the disk 11n, and near one of two walls 11j2, as an example.

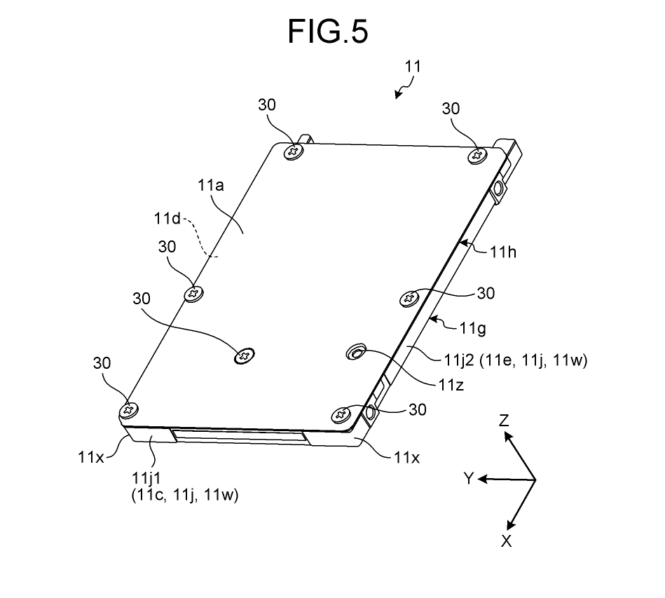

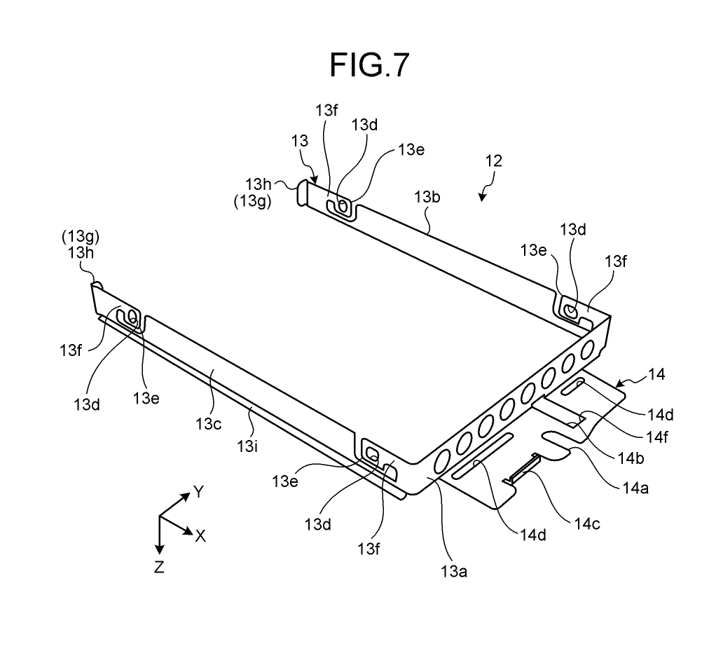

In the first embodiment, as an example, as illustrated in FIGS. 3, 4, and 7, the holder 12 comprises a surrounding portion 13 and a bracket 14 (an attaching portion, a fixed portion, a coupling portion, a connected portions, a support, a guide portion, a plate-like shape portion, a flange) that are integrated to each other. The surrounding portion 13 comprises three frames 13a, 13b, and 13c (walls, plate-like portions), and has an external appearance of a C-shape (U-shape). These three frames 13a, 13b, and 13c have a band-like and plate-like (wall-like) shape having a constant height. The three frames 13a, 13b, and 13c surround three side surfaces 11c, 11d, and 11e of the module 11 (see FIG. 5), but not a side surface 11f where a connector 15 (a second connector) is provided. The surrounding portion 13 also comprises a plurality of (in the first embodiment, four, as an example) holding portions 13e. Each of the holding portions 13e has an opening 13d through which the screw 30 being a coupler for coupling the module 11 and the holder 12 is passed. Each of the holding portions 13e is connected to the frame 13b or the frame 13c via an arm 13f. The holder 12 is made of a metallic material having elasticity and conductivity (e.g., a sheet metal), as an example.

The two frames 13b and 13c extend side by side (in the first embodiment, in parallel, as an example). An end 13g of each of the frames 13b and 13c, being the end on a side of the connector 15, is bent in a direction approaching each other. In other words, the end 13g has a bent portion 13h. Each of the frames 13b and 13c also comprises a flange 13i (a reinforcing portion). The flange 13i extends along a side edge of each of the frames 13b and 13c, from the side of the connector 15 (the opposite side of the bracket 14) to the side of the bracket 14. In the first embodiment, the flange 13i extends, in the longitudinal direction, across two of the holding portions 13e arranged at both of the longitudinal ends of each of the frames 13b and 13c, and between the end 13g and the frame 13a.

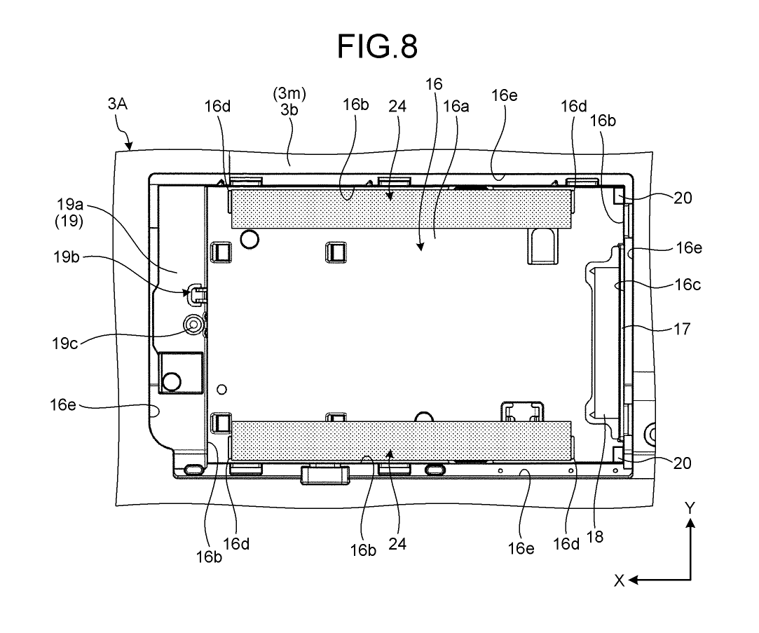

The bracket 14 is used to fix the sub-assembly 10 to the housing 3A. The bracket 14 protrudes along the first surface 11a, outwardly from the frame 13a, on the side of the first surface 11a located on the opposite side of the side surface 11c where the connector 15 is provided. The bracket 14 has a flat, plate-like shape. On the tip-side edge of the bracket 14, a cutout 14a (an opening, a penetrating portion, a slit) is formed. A screw (not illustrated) being a fixture is passed through the cutout 14a. The cutout 14a opens to a direction in which the connector 15 is separated from a connector 18 (a first connector, see FIG. 8, for example) that is coupled with the connector 15 (in other words, a direction opposite to the direction in which the connector 15 and the connector 18 are coupled to each other (inserted into or engaged with the connector 18, the X direction)). The bracket 14 also comprises a slit 14b (an opening, a penetrating portion, a cutout) extending at a constant width along the direction in which the connector 15 is engaged with the connector 18 (the X direction). On the tip side of the bracket 14, a claw-like projection 14c that is cut out and bent toward the second surface 11b is provided. The bracket 14 also comprises a plurality of slits 14d (openings, through holes) extending linearly along the frame 13a (along the Y direction).

In the first embodiment, as an example, as illustrated in FIGS. 8 to 10, the sub-assembly 10 is placed in a recess 16 (an accommodating part, a module accommodating part, a housing accommodating part, an opening) formed on the wall 3m of the housing 3A and having a rectangular opening in the plan view, as an example. The connector 18 implemented on a board 17 (a circuit board) is electrically connected to (coupled to, engaged with) the connector 15 implemented on the module 11. A bottom surface 16a of the recess 16 has a rectangular shape (in the first embodiment, an oblong shape, as an example) in the plan view. The connector 18 is placed on one side surface 16b that is located on one side of the recess 16 in the X direction. The connector 18 is relatively firmly fixed to the board 17 that is placed inside of the housing 3A, and exposed (protrudes) to the inside of the recess 16 (facing the recess 16) through an opening 16c formed on the side surface 16b. There is a gap, at least partially, between each of the side surfaces 16b that are positioned on both sides of the recess 16 in the Y direction and each of side surfaces 13j of the sub-assembly 10 that is placed in the recess 16. On the other side surface 16b of the recess 1, a guiding member (e.g., an elastic member) for guiding (moving) the sub-assembly 10 when the connector 15 is inserted into the connector 18, or a member functioning as a conductive member for grounding the sub-assembly 10 may be provided.

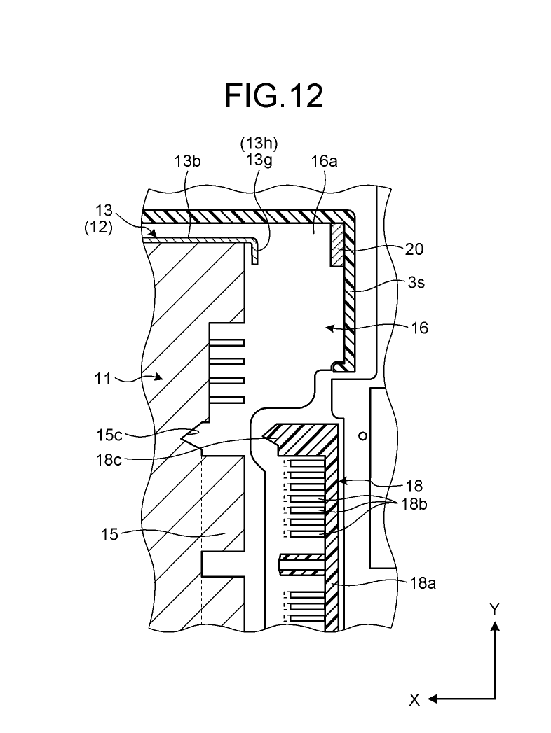

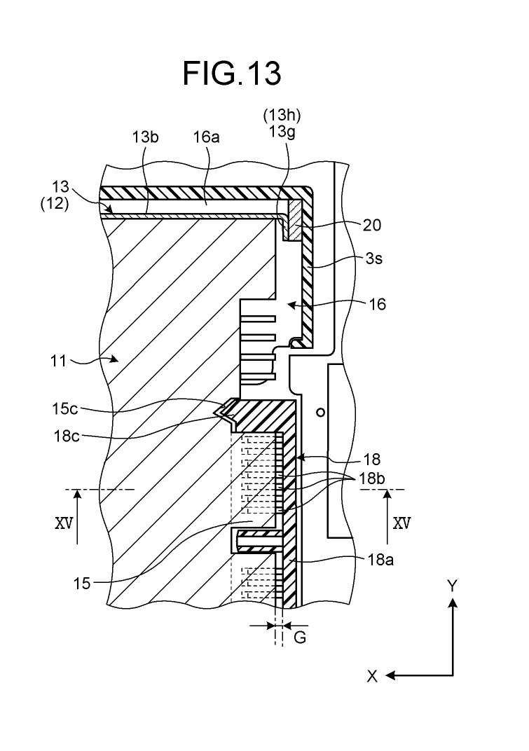

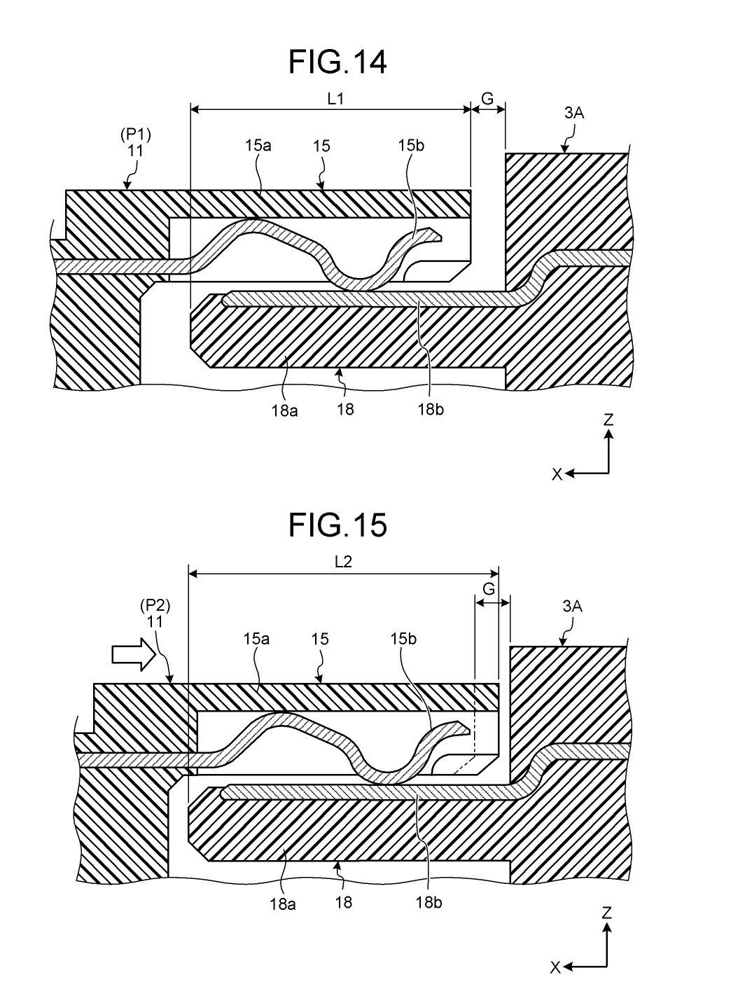

In the first embodiment, as an example, the connector 18 is configured as a flat female connector that is long in the Y direction. The connector 18 comprises a base 18a extending along the Y direction and a plurality of terminals 18b aligned in the Y direction, as illustrated in FIGS. 12 and 13. The board 17 is housed in the housing 3A, and is fixed to the housing 3A with screws (not illustrated) or the like. The connector 15 is configured as a flat male connector that is long in the Y direction, and comprises a base 15a extending along the Y direction and a plurality of the terminals 15b aligned in the Y direction, as illustrated in FIGS. 14 and 15.

On the other end of the recess 16 in the X direction, a stepped portion 19 extending approximately in parallel with the bottom surface 16a is arranged between the bottom surface 16a and the edge of the opening of the recess 16. In a configuration in which the sub-assembly 10 is placed in the recess 16, a rear surface 14e (see FIG. 4) of the bracket 14 is held in contact with a top surface 19a of the stepped portion 19. The connector 15 provided on the side surface 11c is engaged with and mounted on the connector 18 exposing into the recess 16. The connector 18 and the connector 15 are coupled in the longitudinal direction of the sub-assembly 10 (the X direction).

In the first embodiment, as illustrated in FIG. 8, a plurality of (in the first embodiment, two, as an example) buffers 24 (flexible members, suppressing members, buffering portions, flexible portions, suppressing portions, second buffers, cushions, shock absorbers) are provided on the bottom surface 16a of the recess 16, as an example. Each of the buffers 24 is provided on each end of the bottom surface 16a (the recess 16) in the short side direction, and extends in a band-like shape along the longitudinal direction between longitudinal ends of the bottom surface 16a (the recess 16). Each of the buffers 24 has a flat, thin, and long cuboid shape. The buffers 24 are positioned interspaced from the respective side surfaces 16b in the longitudinal direction. Each of the buffers 24 may be aligned using the edge of openings 16d formed on the bottom surface 16a. The buffers 24 are made of a foamed synthetic resin material or elastomer, for example. The buffers 24 may be adhered to the bottom surface 16a using an adhesive agent or the like, as an example.

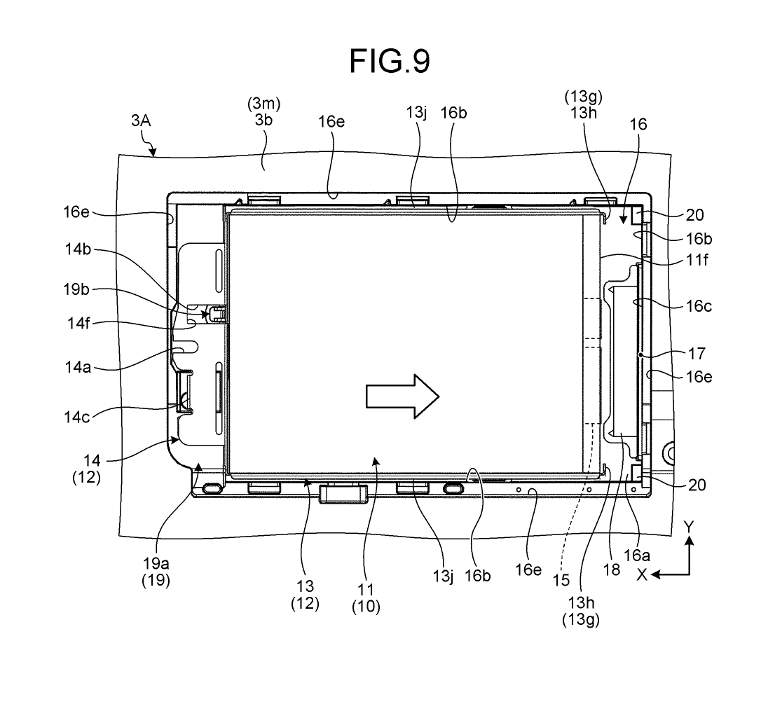

As illustrated in FIG. 9, in an initial configuration after the sub-assembly 10 is inserted into the recess 16, the sub-assembly 10 is placed closer to a side that is opposite of where the connector 18 is provided inside the recess 16. The rear surface 14e of the bracket 14 abuts against the top surface 19a of the stepped portion 19, and an engaging portion 19b (a protrusion, a projection, a contacting portion, a hook portion, a stopper) protruding from the stepped portion 19 is passed through the slit 14b. The width of the engaging portion 19b is slightly smaller than the width of the slit 14b.

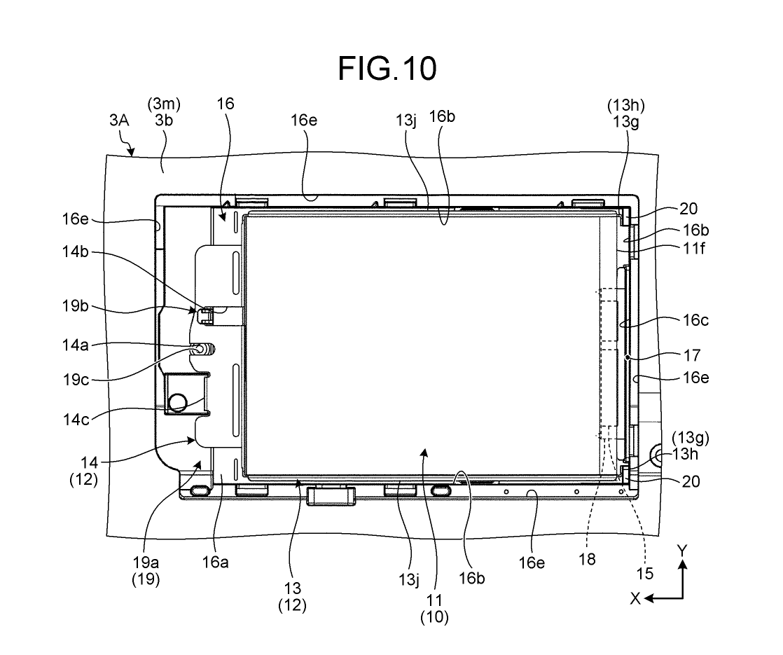

When a worker slides the sub-assembly 10 toward the connector 18 (to the right side in FIGS. 9 and 10) while pressing down the sub-assembly 10 toward the bottom of the recess 16 (toward the bottom surface 16a, the buffers 24) by applying a relatively small force, the connector 15 becomes engaged with the connector 18. At the same time, on the opposite side of these connectors, the engaging portion 19b is engaged with an engaging portion 14f (an edge portion, a stopper) provided on the slit 14b that is located on the opposite side of the connector 15. In this manner, the sub-assembly 10 is placed in and temporarily held in the recess 16 (without being fixed with the screws 30 and the like being couplers).

As the sub-assembly 10 is moved from the position illustrated in FIG. 9 to the position illustrated in FIG. 10, the connector 18 and the connector 15 move from the respective positions illustrated in FIG. 12 to the positions illustrated in FIG. 13. As illustrated in FIGS. 12 and 13, parts 20 are provided on the side surface 16b of the recess 16 (a wall 3s of the housing 3A forming the recess 16), at positions facing the respective bent portions 13h each of which is arranged on the corresponding end 13g of the frame 13b of the holder 12. In a configuration in which the sub-assembly 10 is mounted on the housing 3A as illustrated in FIG. 8, the ends 13g of the holder 12 abut against the parts 20, respectively. In this manner, the parts 20 can function as members for aligning the ends 13g, and aligning the sub-assembly 10.

In the first embodiment, as an example, as illustrated in FIG. 13, when the sub-assembly 10 is mounted on the housing 3A, the connector 15 is not fully inserted into the deepest part of the connector 18, and a gap G is formed between the connector 18 and the connector 15. Although the gap G is formed between the connector 18 and the connector 15, the terminals 18b on the connector 18 and the terminals 15b on the connector 15 are still electrically connected, as illustrated in FIG. 15.

Each of the parts 20 is a relatively hard member, e.g., made of a metallic material. Therefore, even when an inertial force acts on the sub-assembly 10 from the left side to the right side in FIG. 10, e.g., when the housing 3A is dropped, or even when an external force is applied to the sub-assembly 10 from the right side in FIG. 10, the load is communicated to the ends 13g of the holder 12 via the parts 20. The parts 20 are examples of a stiff body or a load communicating member. In the first embodiment, as an example, the arms 13f are examples of a narrow portion that is narrower (with a smaller cross-section area) than the other part (general part) of the holder 12, are examples of a stress concentrating portion, or are examples of a fragile portion that is fragile relatively to the other part of the holder 12. When a load is communicated to the ends 13g of the holder 12 via the parts 20, the stress is more concentrated on the arms 13f being narrow portions. Therefore, the holder 12 including the arm 13f will be plastically deformed more easily. The plastic deformation mentioned herein means an irreversible deformation (a permanent deformation), not an elastic deformation that is reversible after deformation. A plastic deformation is not limited to a bent such as buckling, but also may be a rupture or an extension, for example.

As described above, in the first embodiment, the gap G is formed between the connector 18 and the connector 15. Therefore, in the first embodiment, because the connector 18 and the connector 15 abut against each other (are propped by each other), a deformation of the arm 13f can be suppressed from being interrupted.

In other words, as illustrated in FIGS. 14 and 15, as the arms 13f (a shock absorber) are buckled (deformed, plastically deformed, bent), the module 11 and the connector 15 are moved from a first position P1 (a first position, an initial position, a mounted position) to a second position P2 (a second position, a moved position), in relation to the housing 3A. The first position P1 is the initial position where the module 11 is positioned after the sub-assembly 10 is inserted into the housing 3A, and where the connector 15 is relatively loosely inserted into the connector 18. The second position P2 is a position of the module 11 that is closer to the connector 18, and where the connector 15 is inserted into the connector 18 relatively deeper than in the first position P1. In other words, the module 11 as a module is movable at least between the first position P1 and the second position P2, and the arms 13f as an example of the shock absorber are buckled (deformed, plastically deformed, or bent) as the module 11 being a module moves from the first position P1 to the second position P2 (moved relatively). Being movable herein means not being movable under a normal condition, but means that the module becomes movable in an abnormal condition, e.g., when the television receiver 1A as an electronic device is dropped, that is, a load acting on the arms 13f being an example of the shock absorber or a stress caused thereby exceeds a predetermined threshold (e.g., limit, yield point, 0.2 percent proof stress).

A length L2 in which the connector 18 and the connector 15 are engaged with each other (a coupled length, the length at which one is laid on top of the other) at the second position P2 is longer than a length L1 (a coupled length, the length at which one is laid on top of the other) in which the connector 18 and the connector 15 are engaged at the first position P1 (L1<L2). It is preferable for the second position P2 to be the deepest position where the connector 15 can be inserted into the connector 18, which is determined by the structures of the connector 18, the connector 15, and other parts, or to be a position more in the front side of the deepest position in the inserting direction. In other words, the engaging length L2 is preferably equal to or shorter than an engaging length L3 (not illustrated) at the deepest position (most rear position) (L2≦L3). This is because, if the connector 15 is inserted further into the connector 18 exceeding the deepest position, the connector 18, the connector 15, or other parts may get damaged. The deepest position may be defined as a position at which an engaging portion 18c (abutting portion) provided as a projection, for example, on the connector 18 abuts against and engaged with an engaging portion 15c (an abutting portion) provided as a recess on the connector 15 (an abutting position, an engaging position), for example, but is not limited thereto.

In the first embodiment, in both of the configuration in which the sub-assembly 10 is mounted on the housing 3A (that is, a configuration in which the connector 18 and the connector 15 are engaged with each other with the gap G therebetween, a configuration in which the module 11 is located at the first position P1) illustrated in FIG. 14 and the configuration illustrated in FIG. 15 in which the connector 15 is engaged deeper into the connector 18 as the arms 13f are deformed (the arrangement in which the module 11 is at the second position P2), and in configurations between these two configurations as well, the terminals 18b on the connector 18 and the terminals 15b on the connector 15 are kept in contact with each other and kept continuous, and are electrically connected to each other. In other words, the board 17 is kept electrically connected to the module 11 via the connector 18 and the connector 15. Therefore, even when the arms 13f are deformed because some shock is applied to the housing 3A, for example, the electrical connection between the module 11 and the circuit board (not illustrated) is maintained, and, therefore, operations of the television receiver 1A (accesses to the module 11) is less interrupted, advantageously. It is more preferable for the board 17 to be kept electrically connected to the module 11 via the connector 18 and the connector 15, even when the module 11 comes to the deepest position.

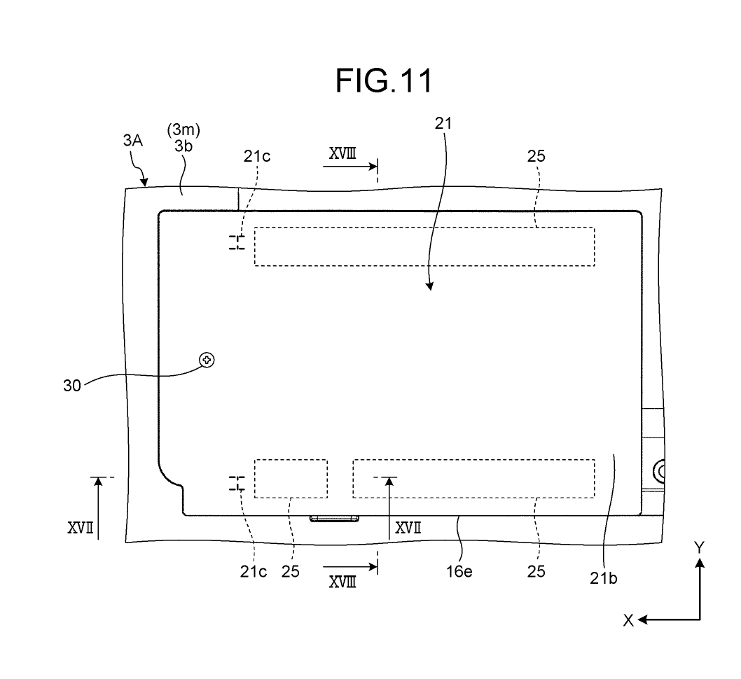

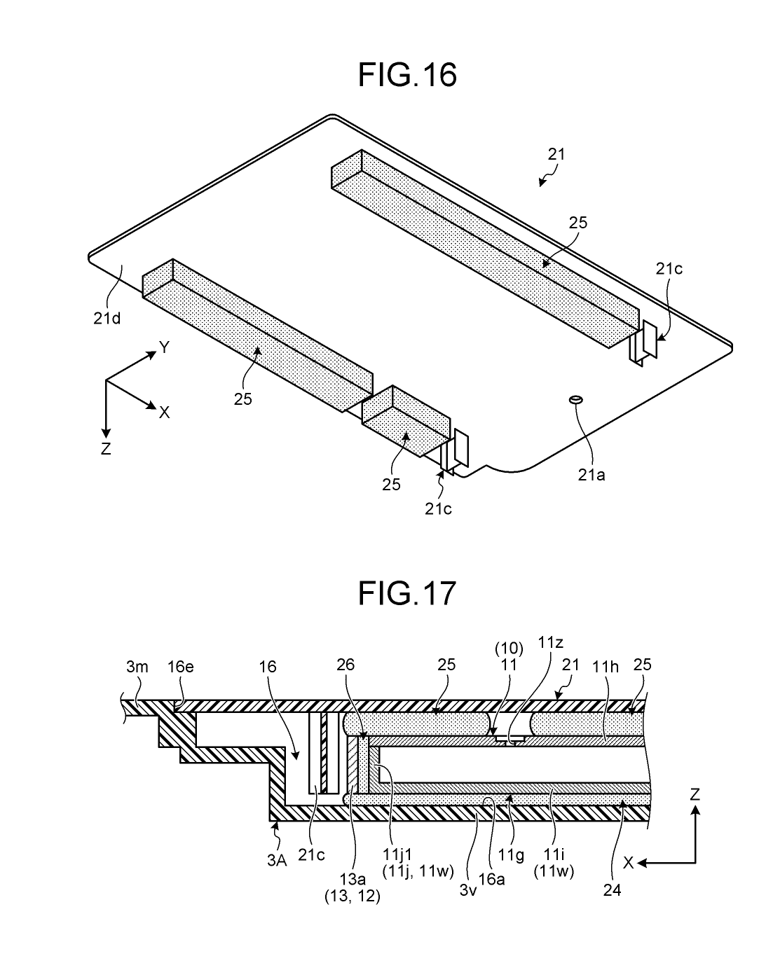

In the first embodiment, as an example, as illustrated in FIG. 11, a cover 21 (a cover, a covering member, a plate-like member, a plate, a wall, a member, a part) for covering the recess 16 is provided. The cover 21 has a rectangular, plate-like shape. The cover 21 is attached to an opening 16e, to close the recess 16. The cover 21 faces the second member 11h of the housing 11w. The cover 21 comprises a coupling portion 21a (in the first embodiment, an opening, as an example), as illustrated in FIG. 16. The cover 21 and the housing 3A are coupled by a coupler 30 (see FIG. 11) passed through the coupling portion 21a from a surface 21b (a frontal surface, a first surface) of the cover 21, and are coupled to a coupling portion 19c of the housing 3A. This coupler 30 is also passed through the cutout 14a on the bracket 14. In other words, by coupling the coupler 30 to the coupling portion 19c, the bracket 14, and the module 11 are fixed to the housing 3A, while the bracket 14 is held between the housing 3A and the cover 21. In the first embodiment, as an example, the cutout 14a extends in a direction in which the connector 15 and the connector 18 are brought closer to each other or separated from each other (in the X direction).

In the first embodiment, as an example, a relative movement of the module 11 with respect to the housing 3A in the direction in which the connectors 15 and 18 are separated from each other (in the left direction in FIGS. 9 to 15) can be suppressed by protrusions 21c (suppressors) that are fixed to the housing 3A, or provided to the cover 21 that is a part of the housing 3A. The protrusions 21c suppress the connectors 15 and 18 from separating from each other, and from being electrically disconnected. In the first embodiment, as an example, as illustrated in FIGS. 16 and 17, each of the protrusions 21c protrudes from a surface 21d (a rear surface) of the cover 21 on the opposite side of the connector 18 of the connector 15 (in the first embodiment, as an example, on the opposite side of the connector 18 in the housing 11w; on the left side in FIG. 17) into the recess 16, and faces the wall 11j of the housing 11w and the frame 13a of the holder 12. In the first embodiment, as an example, each of the protrusions 21c has an H shape. In this manner, a sectional secondary moment can be further increased, and the protrusions 21c being relatively light-weighted and having a relatively stiff structure can be achieved. The H-shape is merely an example, and may have another sectional shape.

In the first embodiment, as an example, as illustrated in FIGS. 16 and 11, a plurality of (in the first embodiment, three, as an example) buffers 25 (flexible members, suppressing members, buffering portions, flexible portions, suppressing portions, first buffers, cushions, shock absorbers) are provided on the surface 21d of the cover 21. The buffers 25 are provided on respective ends of the surface 21d (the recess 16) in the short side direction, and extend in a band-like shape in the longitudinal direction between longitudinal ends of the surface 21d (the recess 16). Each of the buffers 25 has a flat, thin, and long cuboid shape. The buffers 25 may be aligned using protrusions (e.g. ribs not illustrated) provided on the surface 21d. The buffers 25 may be made of a foamed synthetic resin material or elastomer, for example. The buffers 25 may be adhered to the surface 21d using an adhesive agent or the like, as an example.

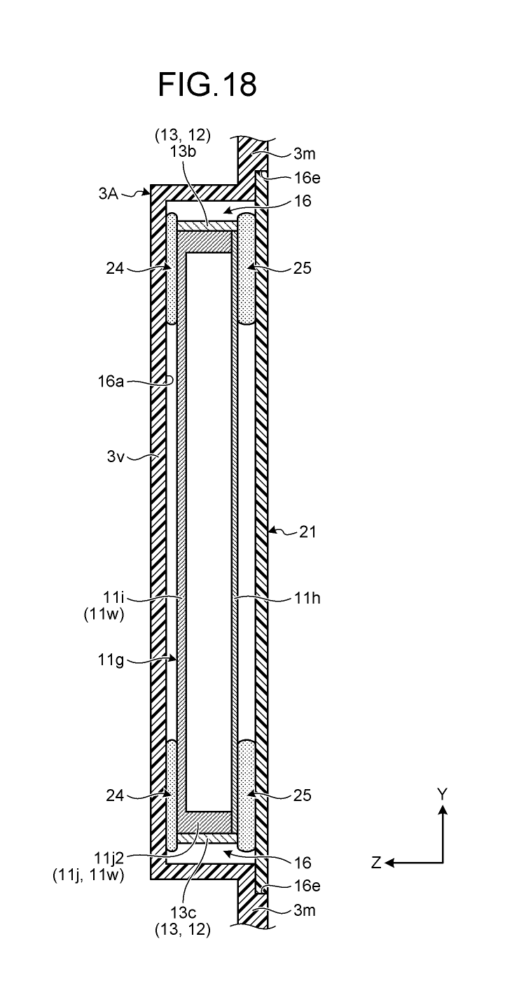

In the first embodiment, as an example, as illustrated in FIGS. 17 and 18, the buffers 24 are positioned between a wall 3v of the housing 3A (the bottom surface 16a of the recess 16) and the housing 11w of the module 11, and the buffers 25 are positioned between the cover 21 and the housing 11w. The buffers 24 and 25 are nipped and compressed flexibly between the housing 11w and the housing 3A or the cover 21 in an assembled configuration. Because the buffers 24 and 25 are compressed (pressed flat) in an initial configuration, the buffers 24 and 25 can buffer (reduce) an applied force (a load) more effectively. Furthermore, because the buffers 25 are thicker than the buffers 24, the buffers 24 and 25 can buffer (reduce) a force applied from the outside of the housing 3A (from the side of the cover 21) (a load; a load applied from the top in FIG. 17 or applied from the right side in FIG. 18) more effectively.

In the first embodiment, as an example, each of the buffers 24 and 25 extends in the longitudinal direction of the recess 16. Therefore, according to the first embodiment, as an example, a larger area of the buffers 24 and 25 can be reserved compared with when each of the buffers 24 and 25 extends in the short side direction, for example. Therefore, a higher buffering effect can be achieved.

Furthermore, in the first embodiment, as an example, the buffers 24 and 25 act as a resistance when the housing 11w of the module 11 moves relatively to the housing 3A or the cover 21 in the direction along the bottom surface 16a of the recess 16 (the direction along the XY plane). In other words, the buffers 24 and 25 not only have a buffering effect against a force in the direction in which the module 11 and the cover 21 are laid over each other, but also has a buffering effect to a force (a load) in a direction intersecting with such a direction in which the module 11 and the cover 21 are laid over each other (the direction along the bottom surface 16a of the recess 16, and the first surface 11a and the second surface 11b of the module 11). In particular, in the first embodiment, because the buffers 24 and 25 extend in the direction in which the connectors 15 and 18 are coupled (in the direction in which the connectors 15 and 18 are plugged, inserted, removed, or separated), as an example, the connectors 15 and 18 can be suppressed from being damaged or being electrically disconnected, for example.

The buffers 24 and 25 are also laid over the wall 11j of the housing 11w (first wall) and the frames 13a, 13b, and 13c (walls, second walls) of the holder 12 in a direction in which the module 11 (the housing 11w) and the cover 21 are laid over each other (the Z direction). Therefore, a force (a load) applied from the housing 3A or the cover 21 to the module 11 (the housing 11w) is communicated to the wall 11j and the frames 13a, 13b, and 13c via the buffers 24 and 25. Therefore, such a force (a load) is less communicated to the wall 11i of the first member 11g or to the second member 11h (a wall) of the module 11. As mentioned earlier, the shaft 11p rotatably supporting the arm 11r extends between the wall 11i of the first member 11g and the second member 11h. In other words, the ends of the shaft 11p are respectively supported by the wall 11i and the second member 11h. It has been discovered that, by researches conducted by the inventors, when an abnormal (shocking) external force (an inertial force, for example) is applied to the module 11, e.g., when the housing 3A is dropped, reading or writing performed by the head 11t might fall into an abnormal condition because of the force (a load) applied to the wall 11i or the second member 11h. Regarding this point, in the first embodiment, as an example, because the buffers 24 and 25 are laid over the wall 11j of the housing 11w and the frames 13a, 13b, and 13c (walls, second walls) of the holder 12 in the direction in which the module 11 (the housing 11w) and the cover 21 are laid over each other (the Z direction), and buffer (reduce) the force (a load) applied to the wall 11i and the second member 11h, reading or writing performed by the head 11t is suppressed from falling into an abnormal condition. Furthermore, as may be understood from FIGS. 6, 11, and the like, in the first embodiment, as an example, the buffers 24 and 25 are positioned offset from the rotational axis of the disk 11n (the shaft 11s) and from the rotational axis of the arm 11r (the shaft 11p). Therefore, according to the first embodiment, the force (a load) is suppressed from being communicated to the disk 11n or the arm 11r via the buffers 24 and 25, and reading or writing performed by the head 11t is suppressed from falling into an abnormal condition.

Furthermore, in the first embodiment, as an example, as illustrated in FIG. 17, the buffers 25 are positioned offset from the ventilation hole 11z. In other words, the buffers 25 does not cover (block) the ventilation hole 11z. In this manner, inconveniences caused when the ventilation hole 11z is covered (e.g., a temperature increase) can be suppressed from occurring.

In the first embodiment, as an example, as illustrated in FIG. 17, a buffer 26 is positioned between the frame 13a (a wall) of the holder 12 and a wall 11j1 of the housing 11w. The buffer 26 extends in a band-like shape along the frame 13a and the wall 11j1, as an example. The buffer 26 is made of a foamed synthetic resin material or elastomer, for example. The buffer 26 is nipped and compressed flexibly between the frame 13a and the wall 11j1 in an assembled configuration, as an example. The buffer 26 can suppress a force (a load) from being communicated from the protrusion 21c of the cover 21 or from the frame 13a (the holder 12) to the wall 11j1 (the module 11), as an example.

Furthermore, in the first embodiment, as an example, it is preferable that the module 11, the cover 21, the housing 3A, and the like are electrically connected via the buffers 24 and 25, and the ground potential is shared between the module 11 and the cover 21, as an example. To share the ground potential, the housing 3A, the cover 21, the protrusion 21c, the buffers 24 and 25, the frame 13a, the holder 12, the housing 11w, and the like may be made of a conductive material (e.g., a metallic material with a conductive property), or a conductive member may be provided, at least partially, to an area that is brought into contact with other parts. In the latter configuration, a conductive film or tape may be adhered to the part, so that the parts are provided with a conductive area.

In the first embodiment, as an example, a plurality of components (elements, electronic components, electric components) are housed in the housing 3A. The components and the like implemented on the board 17 form at least a part of a controlling circuit (not illustrated). The controlling circuit may include a video signal processing circuit, a tuner, a high-definition multimedia interface (HDMI) signal processor, an audio-video (AV) input terminal, a remote controller signal receiver, a controller, a selector, an on-screen display, a storage (e.g., a read-only memory (ROM), a random access memory (RAM), a hard disk drive (HDD)), and an audio signal processing circuit. The controlling circuit controls video outputs (e.g., moving images or still images) from the screen 4a of the display device 4, sound outputs from a speaker (not illustrated), and light emissions from a light emitting diode (LED) (not illustrated). The display device 4, the speaker, the LED, and the like are examples of an output module.

As explained above, in the first embodiment, as an example, the television receiver 1A comprises the buffers 25 positioned between the housing 11w of the module 11 and the cover 21 and extending along the longitudinal direction of the recess 16. Therefore, according to the first embodiment, as an example, the buffers 25 can be arranged at a longer length between the module 11 and the cover 21, so that a higher buffering effect can be achieved, as an example.

Furthermore, in the first embodiment, as an example, the television receiver 1A comprises the buffers 24 positioned between the housing 3A and the housing 11w of the module 11, and extending in the longitudinal direction of the recess 16. Therefore, according to the first embodiment, the buffers 24 can be arranged at a longer length between the housing 3A and the module 11, as an example, and a higher buffering effect can be achieved, as an example.

Furthermore, in the first embodiment, as an example, the buffers 24 and 25 extend in the direction in which the connectors 15 and 18 are coupled (in the direction in which the connectors 15 and 18 are plugged, inserted, removed, or separated). Therefore, according to the first embodiment, as an example, the buffers 24 and 25 can suppress damages of and electrical disconnection between the connectors 15 and 18, for example.

Furthermore, in the first embodiment, as an example, the buffers 24 and 25 are laid over the wall 11j of the housing 11w and the frames 13a, 13b, and 13c of the holder 12 (walls, second walls) in the direction in which the module 11 (the housing 11w) and the cover 21 are laid over each other (the Z direction). Therefore, according to the first embodiment, as an example, a force (a load) acting on the wall 11i or the second member 11h via the buffers 24 and 25 is buffered (reduced), and reading or writing performed by the head 11t is suppressed from falling into an abnormal condition, as an example.

Furthermore, in the first embodiment, as an example, the buffers 24 and 25 are positioned offset from at least one of the rotational axis of the disk 11n and the rotational axis of the arm 11r. Therefore, according to the first embodiment, as an example, a force (a load) is suppressed from being communicated to the disk 11n and the arm 11r via the buffers 24 and 25, and reading or writing performed by the head 11t is suppressed from falling into an abnormal condition, as an example.

### Second Embodiment

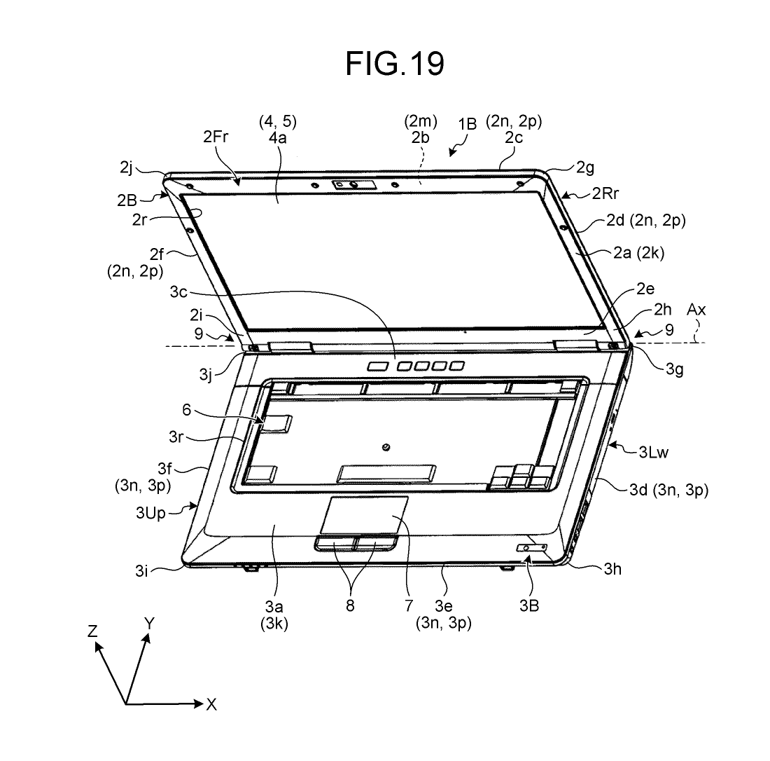

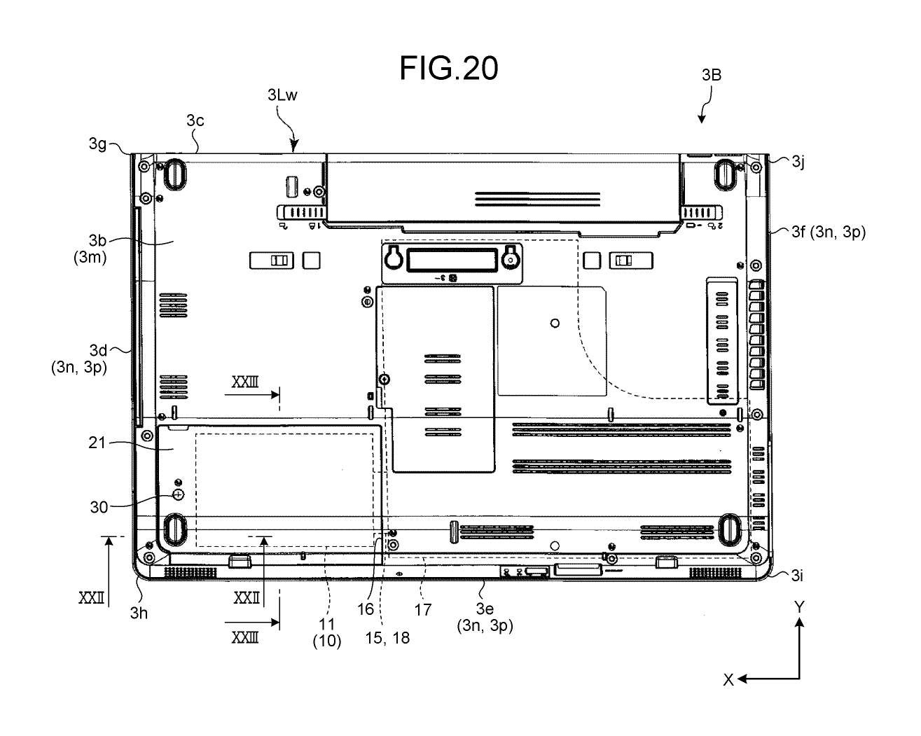

An electronic device 1B according to a second embodiment is a so-called laptop (clamshell) computer, as an example. In the second embodiment, the electronic device 1B comprises a first housing 3B (a housing) and a second housing 2B (another housing) as illustrated in FIG. 19, as an example. The board 17 (see FIG. 20) is housed in the first housing 3B (a first part), and at least a part of the display device 4 is housed in the second housing 2B (a second part). A keyboard 6 (an input operation module, input a receiving module, an input module), a touchpad 7 (an input operation module, an input receiving module, an input module), and click buttons 8 (an input operation module, an input receiving module, an input module) are arranged on the first housing 3B.

The first housing 3B and the second housing 2B are rotatably connected by a hinge 9 (a connected portion, a linking portion, a rotatable support, a hinge mechanism, a connecting mechanism, a linking mechanism, a rotatably supporting mechanism). The first housing 3B and the second housing 2B are rotatably connected by the hinge 9 between an opened configuration illustrated in FIG. 19 and a folded configuration not illustrated. In the second embodiment, as an example, the hinge 9 connects the first housing 3B and the second housing 2B rotatably about a rotation axis Ax. The screen 4a of the display device 4 is exposed through an opening 2r formed on a surface 2a (a frontal surface, a surface, a surface portion) of the second housing 2B. The keyboard 6, the touchpad 7, the click buttons 8, and the like are exposed on a surface 3a (an upper surface, a frontal surface, a first surface, a first surface portion) of the first housing 3B. When the electronic device 1B is folded, the surface 3a of the first housing 3B is brought into contact with the surface 2a of the second housing 2B, and the screen 4a, the keyboard 6, the touchpad 7, the click buttons 8, and the like are hidden by the first housing 3B and the second housing 2B. When the electronic device 1B is opened, the surface 3a of the first housing 3B and the surface 2a of the second housing 2B are exposed, the screen 4a, the keyboard 6, the touchpad 7, the click buttons 8, and the like are made available for use (for viewing and operations). In FIG. 19, only some keys in the keyboard are illustrated.

In the second embodiment, as an example, as may be understood from FIG. 19, the second housing 2B has an external appearance of a rectangular shape (in the second embodiment, an oblong shape, as an example) in front view and the rear view. In the second embodiment, as an example, the second housing 2B has a cuboid shape that is thin and flat in the front-back direction (the thickness direction of the second housing 2B). The second housing 2B has the surface 2a, and a surface 2b (a rear surface, a back surface, a surface portion) located on the opposite side of the surface 2a. The surface 2a and the surface 2b are laid approximately in parallel (in the second embodiment, in parallel, as an example). The second housing 2B also has four ends 2c to 2f (side portions, edge portions) and four corners 2g to 2j (pointed portions, curved portions, ends) in the front view. The ends 2c and 2e are examples of a longer side. The ends 2d and 2f are examples of a shorter side.

The second housing 2B also comprises a wall 2k (a part, a plate, a frame, a front wall, a frontal wall, a top wall) including the surface 2a, and a wall 2m (a part, a plate, a rear wall, a back wall, a bottom wall) including the surface 2b. The walls 2k and 2m both have a rectangular shape (in the second embodiment, an oblong shape, as an example). The wall 2k also has a frame-like shape, and the wall 2m has a plate-like shape. The second housing 2B also comprises four walls 2n (parts, plates, side walls, end walls, standing walls, stretched portions) each of which includes a surface 2p (a side surface, a circumferential surface) stretching across the wall 2k and the wall 2m. A rectangular opening 2r is formed on the wall 2k.

The second housing 2B is made from a combination of a plurality of parts (divided portions, member). The second housing 2B comprises a first member 2Fr (first part, front side member, cover, bezel, frame) at least including the wall 2k, and a second member 2Rr (second part, rear side member, base, bottom, plate, cover) at least including the wall 2m, as an example. In the second embodiment, as an example, the walls 2n are configured as a part of the second member 2Rr. The first member 2Fr, the second member 2Rr, and the like may be made of a metallic material or a synthetic resin material, for example.

In the second embodiment, as an example, the display device 4 (a display unit, a display, a panel, a display component) is housed in the second housing 2B. Specifically, the screen 4a of the display device 4 located on the side of the surface 2a is exposed to the front side (outside) of the second housing 2B through the opening 2r. A user can view the screen 4a from the front side through the opening 2r. The display device 4 has an external appearance of a rectangular shape (in the second embodiment, an oblong shape, as an example) in the front view. The display device 4 also has a cuboid shape that is thin and flat in the front-back direction. The display device 4 is an LCD, an GELD, or a PDP, for example.

In the second embodiment, as an example, a transparent, relatively thin, and rectangular input operation panel 5 (as an example, a touch panel, a touch sensor, an operation surface, an input operation module, an input receiving module) is placed on the front side (frontal side, the side of the wall 2k) of the display device 4. The input operation panel 5 covers the screen 4a. An operator (e.g., a user) can make inputs by making operations such as touching, pressing, rubbing the input operation panel 5, or moving a hand, a finger, or stylus near the input operation panel 5. Light output from the screen 4a of the display device 4 passes through the input operation panel 5 and travels to the front side (outside) of the second housing 2B through the opening 2r on the wall 2k. The input operation panel 5 is an example of an input module. In the first embodiment, as an example, the display device 4 and the input operation panel 5 are fixed to (supported by) one of the first member 2Fr and the second member 2Rr with fixtures (fixing parts, clamps; e.g., screws, clamps, or parts, not illustrated), an adhesives (e.g., an adhesive agent, or a double-sided adhesive tape, not illustrated), and the like.

In the second embodiment, as may be understood from FIGS. 19 and 20, the first housing 3B has an external appearance of a rectangular shape (in the second embodiment, an oblong shape, as an example) in the front view and the rear view, as an example. In the second embodiment, the first housing 3B has a cuboid shape that is flat in the up and down direction (the thickness direction of the first housing 3B, the Z direction), as an example. The first housing 3B has a surface 3a (an upper surface, a frontal surface, a surface portion), and a surface 3b (a bottom surface, a back surface, a surface portion) located on the opposite side of the surface 3a. The surface 3a and the surface 3b are laid approximately in parallel (in the second embodiment, in parallel, as an example). The first housing 3B has four ends 3c to 3f (side portions, edge portions) and four corners 3g to 3j (pointed portions, curved portions, ends) in the plan view. The ends 3c and 3e are examples of a longer side. The ends 3d and 3f are examples of a shorter side. The first housing 3B functions as an accommodating part for housing components such as the board 17, as an example, and may also function as a support for supporting an object with some weight (e.g., a component).

The first housing 3B also has a wall 3k (a part, a plate, a frame, an upper wall portion, a frontal wall, a top wall) including the surface 3a, and a wall 3m (a part, a plate, a bottom wall, a back wall, a bottom wall) including the surface 3b. The wall 3k and 3m both have a rectangular shape (in the second embodiment, an oblong shape, as an example). The wall 3k also has a frame-like shape, and the wall 3m has a plate-like shape. The first housing 3B also has four walls 3n (parts, plates, side walls, end walls, standing walls, stretched portions) each of which includes a surface 3p (side surface, circumferential surface) stretching across the wall 3k and the wall 3m. A rectangular opening 3r is formed on the wall 3k.

The first housing 3B is made from a combination of a plurality of parts (divided portions, members). The first housing 3B comprises a first member 3Up (a first part, an upper member, a cover, a mask, a plate) including at least the wall 3k, and a second member 3Lw (a second part, a lower member, s base, a bottom, a plate, a cover) including at least the wall 3m, as an example. In the second embodiment, the walls 3n are configured as apart of the second member 3Lw, as an example. The first housing 3B may comprise a third member (a third part, an intermediate member, an inner, a middle frame, a middle plate, not illustrated) interposed between the first member 3Up and the second member 3Lw, in addition to the first member 3Up and the second member 3Lw. Some part of the walls 3k, 3m, and 3n maybe included as a part of the third member. The first member 3Up, the second member 3Lw, the third member, and the like may be made of a metallic material or a synthetic resin material, for example.

In the second embodiment, as an example, one or more boards 17 (circuit boards, control boards, main boards, electric components) are housed in the first housing 3B, as illustrated in FIG. 20. The board 17 is arranged side by side with the keyboard 6 (see FIG. 19) (in the second embodiment, in parallel, as an example).

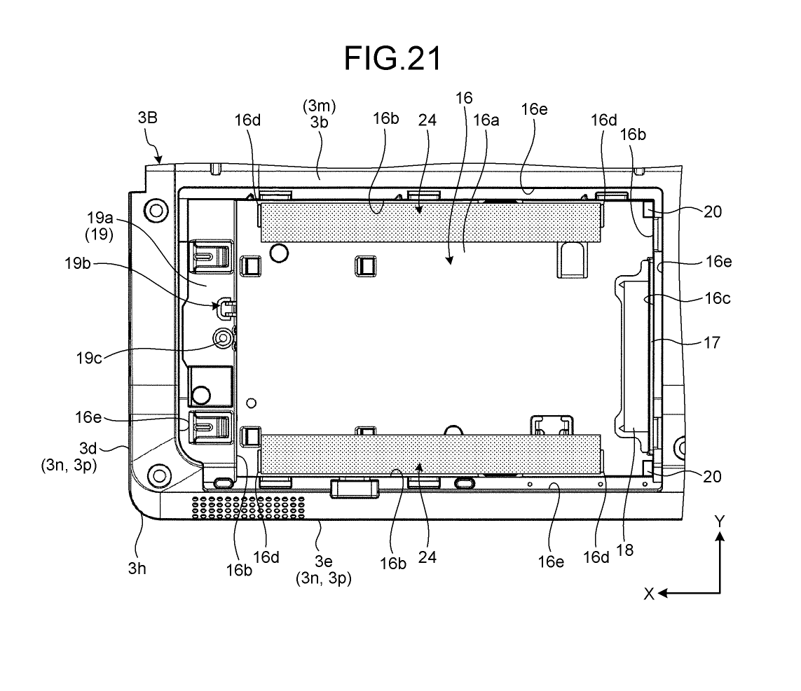

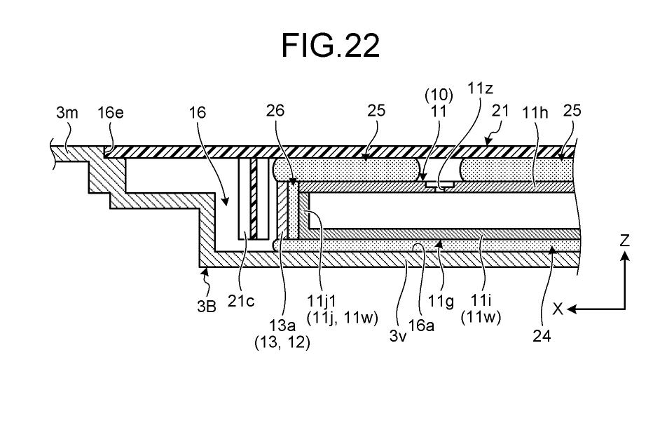

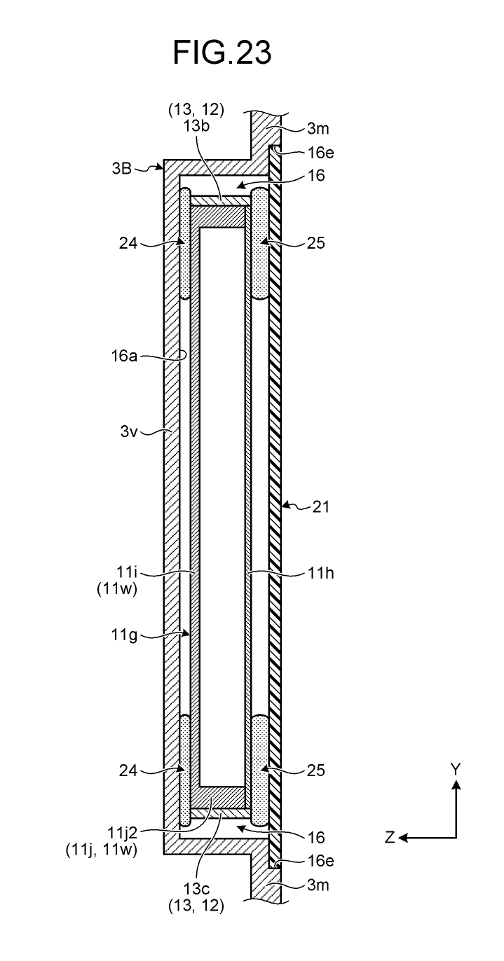

In the second embodiment, as an example, the same recess 16 (an accommodating part) as that in the first embodiment is arranged near the corner 3h of the wall 3m included in the first housing 3B, as illustrated in FIG. 21. The same module 11 (the sub-assembly 10) as that in the first embodiment is accommodated in the recess 16. The opening 16e of the recess 16 is covered by the same cover 21 as that in the first embodiment. In the second embodiment as well, the same buffers 24, 25, and 26 as those in the first embodiment are provided, as illustrated in FIGS. 22 and 23, as an example.

In the second embodiment, as an example, a plurality of components (not illustrated) such as a central processing unit (CPU), a graphic controller, power circuit components, a platform controller hub (PCH), a memory slot connector, an LCD connector, an input/output (I/O) connector, a power coil, an element, a connector, and the like can be implemented on the board 17. A controlling circuit may include a video signal processing circuit, a tuner, an HDMI signal processor, an AV input terminal, a remote controller signal receiver, a controller, a selector, an on-screen display, a storage (e.g., a ROM, a RAM, an HDD, and a solid state drive (SSD)), an audio signal processing circuit, and the like. The controlling circuit controls video outputs (e.g., moving images or still images) from the screen 4a of the display device 4, sound outputs from a speaker (not illustrated), and light emissions from a light emitting diode (LED) (not illustrated). The display device 4, the speaker, the LED, and the like are examples of an output module.

The electronic device 1B according to the second embodiment comprises the same accommodating part 16 and the same module 11 as those included in the television receiver 1A in the first embodiment, and the same the buffers 24, 25, and 26 associated with the accommodating part 16 and the module 11. Therefore, the same results as those achieved in the first embodiment can be achieved.

Furthermore, the configurations and the shapes in each of the embodiments are implementable with some parts replaced. The specifications (e.g., the structure, type, direction, shape, size, length, width, thickness, height, number, arrangement, position, and material) of each of the elements may also be changed as appropriate in the implementations. Furthermore, explained in the embodiment is an example in which, when a force (a load) acts in a direction in which the connectors are coupled (in the direction in which the connectors 15 and 18 are plugged, inserted, removed, or separated), a part of the module, the holder, the housing, the parts, or the like is plastically deformed, to buffer (reduce) the shock (a load). However, the embodiment may be implemented as a configuration in which the shock (a load) is buffered (reduced) by an elastic deformation of the part. As an example, the parts 20 according to the embodiment may be configured as buffering portions that deform elastically. In such a configuration, as an example, the parts 20 may be made of a synthetic resin material or elastomer, for example. In addition, the buffers 25 may be provided with an opening (e.g., a penetrating hole or a cutout) in a manner corresponding to the ventilation hole 11z.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television receiver comprising:
a display device comprising a screen;
a first housing configured to house at least a part of the display device in a state exposing the screen, the first housing comprising an accommodating part and a first connector facing the accommodating part;
a second housing configured to be detachably accommodated in the accommodating part, the second housing comprising a second connector configured to be electrically connected to the first connector;
a cover configured to cover the accommodating part and to be removably placed on the first housing; and
a first buffer between the second housing and the cover, the first buffer being configured to extend in a longitudinal direction of the accommodating part.

2. The television receiver of claim 1, further comprising a second buffer at an opposite side of the cover from the second housing and between the first housing and the second housing, the second buffer being configured to extend in the longitudinal direction.

3. The television receiver of claim 2, wherein the first buffer is thicker than the second buffer.

4. The television receiver of claim 2, wherein at least a part of the first buffer is configured to lie over the second buffer in a direction in which the second housing and the cover lie over each other.

5. The television receiver of claim 1, wherein the first connector and the second connector are configured to be coupled in the longitudinal direction.

6. The television receiver of claim 1, wherein
the second housing comprises a first wall configured to extend along a direction in which the second housing and the cover lie over each other; and
at least a part of the first buffer is configured to lie over the first wall.

7. The television receiver of claim 6, further comprising a second wall configured to be on the second housing, along outside of the second housing with respect to the first wall, wherein
at least a part of the first buffer is configured to lie over the second wall.

8. The television receiver of claim 1, wherein the second housing further comprises:
a first member comprising an opening;
a second member configured to cover the opening;
a disk configured to be rotatably supported by the first member;
a shaft configured to be at a position offset from the disk, and to extend between the first member and the second member; and
an arm configured to support a head facing the disk, and to be rotatably supported by the shaft, wherein
the first buffer is offset from at least one of a first rotational axis of the disk and a second rotational axis of the arm, viewed in a direction in which the second housing and the cover lie over each other.

9. The television receiver of claim 1, wherein
the second housing comprises a ventilation hole facing the cover, and
the first buffer is configured to be offset from the ventilation hole.

10. The television receiver of claim 1, wherein the second housing is configured to be electrically connectable with the first connector at a position between a first position of the first housing and a second position where a distance between the first connector and the second connector is shorter than that of the first position.

11. The television receiver of claim 10, further comprising a buffering portion configured to deform as the second housing is moved from the first position to the second position.

12. An electronic device comprising:
a first housing configured to house a circuit board, the first housing comprising an accommodating part and a first connector facing the accommodating part;
a second housing configured to be detachably accommodated in the accommodating part, the second housing comprising a second connector configured to be electrically connected to the first connector;
a lid configured to cover the accommodating part and to be removably placed on the first housing;
a first buffer between the second housing and the lid, the first buffer being configured to extend in a longitudinal direction of the accommodating part; and
a second buffer at an opposite side of the lid from the second housing and between the first housing and the second housing, the second buffer being configured to extend in the longitudinal direction.

13. An electronic device comprising:
a first housing comprising an accommodating part and a first connector facing the accommodating part;
a second housing configured to be detachably accommodated in the accommodating part, the second housing comprising a second connector configured to be electrically connected to the first connector; and
a buffer configured to face the accommodating part, to be in a direction in which the first connector and the second connector are coupled, and to reduce load to be applied to the second housing.
